(19) United States
(12) Patent Application Publication
(10) Pub. No.: US 2022/0137285 A1
(43) Pub. Date: May 5, 2022

(54) OPTICAL STRUCTURE FOR LIGHT-EMITTING DIODE DEVICE AND LIGHT-EMITTING DIODE DEVICE FOR LIGHTING APPLICATION INCLUDING THE SAME

(71) Applicant: CORNING INCORPORATED, CORNING, NY (US)

(72) Inventors: Euisoo Kim, Seongnam-si (KR); Hong Yoon, Asan-si (KR)

(21) Appl. No.: 17/430,899

(22) PCT Filed: Feb. 17, 2020
(86) PCT No.: PCT/KR2020/002236

§ 371 Date: Aug. 13, 2021

(30) Foreign Application Priority Data
Feb. 20, 2019 (KR) 10-2019-0019944

(51) Int. Cl. F21V 8/00

(52) U.S. Cl. CPC G02B 6/0073; G02B 6/0016; G02B 6/0018; G02B 6/0055; G02B 6/0053

(57) ABSTRACT

An optical structure for a light-emitting diode (LED) device, and an LED device for a lighting application including the same. The optical structure includes a light guide plate and a prism sheet, the light guide plate having first and second surfaces facing away from each other, the prism sheet is disposed on a peripheral portion of the first surface, and includes a plurality of prisms continuously arranged in one direction to form a pattern. At least some prisms have an asymmetrical structure in which light-refracting surfaces have different inclinations.

### CROSS-REFERENCE TO RELATED APPLICATIONS

This application claims the benefit of priority under 35 U.S.C. § 119 of Korean Application Serial No. 10-2019-0019944, filed on Feb. 20, 2019, the content of which is incorporated herein by reference in its entirety.

### TECHNICAL FIELD

The present disclosure relates to an optical structure for a light-emitting diode (LED) device, and an LED device for a lighting application including the same. More particularly, the present disclosure relates to an optical structure for an LED device, in which the thickness of a light guide plate is not limited by the size of LEDs used, and high light efficiency can be obtained, even in the case in which the light guide plate is extremely thin, and an LED device for a lighting application including the same.

### BACKGROUND ART

Reducing the thickness of not only televisions (TVs), but also lighting devices, provides high value to consumers. In general, a light guide plate formed from acryl, having a thickness of 4 mm to 6 mm, is used in residential LED lighting. Even though LEDs having a size of 3 mm or less can be fabricated, it may be difficult to fabricate an LED, among LEDs having the size of 3 mm or less, which produces an intensity of luminance suitable for lighting. In addition, when the light guide plate formed from acryl is excessively thin, the light guide plate may sag downwardly, due to the inherent properties of acryl. Thus, the thickness of a light guide plate formed from acryl can be reduced by a limited amount.

The light guide plate may be implemented as a thin glass substrate, since the glass substrate may only sag to a very small extent, due to the high Young's modulus of glass. However, the use of thin glass substrates is still limited, since LEDs small enough to be applicable to thin glass substrates have not been fabricated to date.

To overcome such problems, i.e. to apply large or relatively-thick LEDs to a thin light guide plate, a solution of disposing an optical coupler between a light guide plate and an LED has been proposed. However, in this case, separate optical couplers are required, depending on the size of LEDs and light guide plates. In addition, separate optical couplers may be required, depending on situations, so that optical couplers may be required in a small number but in a variety of types, thereby increasing costs. In addition, in this case, there are the following problems. Light loss may occur during application of an optical coupler, and the process of attaching the optical coupler between a light guide plate and an LED may not be easy.

### RELATED ART DOCUMENT

Patent Document 1: Korean Patent No. 10-1780426 (Sep. 14, 2017)

### DISCLOSURE OF INVENTION

### Technical Problem

Various aspects of the present disclosure provide an optical structure for a light-emitting diode (LED) device, and an LED device for a lighting application including the same. In the optical structure for an LED device, the thickness of a light guide plate is not limited by the size of LEDs used, and high light efficiency can be obtained even in the case in which the light guide plate is extremely thin.

### Solution to Problem

According to an aspect, an optical structure for an LED device includes: a light guide plate having a first surface and a second surface facing away from the first surface; and a prism sheet disposed on a peripheral portion of the first surface, the prism sheet including a plurality of prisms continuously arranged in one direction to form a pattern. The plurality of prisms include prisms having an asymmetrical structure in which light-refracting surfaces have different inclinations.

Here, the optical structure may further include a reflector disposed on the prism sheet.

Each of the plurality of prisms may be a triangular prism.

Each of the plurality of prisms may have an asymmetrical cross-sectional shape, with oblique sides thereof being asymmetrical with respect to each other.

The cross-sectional shape of the prism may be configured such that an interior angle formed between a base and one side, of the oblique sides, ranges from 7° to 30° and an interior angle formed between the base and the other side, of the oblique sides, ranges from 20° to 60°.

The light guide plate and the prism sheet may be adhered to each other via an adhesive.

Pitches between adjacent prisms among the plurality of prisms may range from 15 μm to 40 μm.

The plurality of prisms may be a stripe pattern.

The width of the prism sheet may be equal to or greater than a width of the LED.

The light guide plate may be a glass substrate.

The thickness of the light guide plate may range from 0.5 mm to 2 mm.

A portion of the reflector may extend onto a side surface of the light guide plate.

The portion of the reflector may further extend onto a rear surface of the LED.

The prism sheet may be provided on a surface of the reflector, facing the first surface of the light guide plate.

The prism sheet may further include: a matrix layer provided below the plurality of prisms; and a number of light-scattering particles dispersed in the matrix layer.

The optical structure may further include a reflective layer covering the prism sheet and having a flat surface.

The optical structure may further include a reflective coating layer with which a surface of the prism sheet is coated.

According to another aspect, an light-emitting device for a lighting application includes: the above-described optical structure; an LED disposed on a rear peripheral portion of the optical structure facing the second surface; and a frame providing a mounting space in which the optical structure and the LED are disposed, and including a bezel provided on a front peripheral portion of the optical structure.

The front peripheral portion of the optical structure may be covered with the bezel.

According to exemplary embodiments, the thickness of a light guide plate is not limited by the size of LEDs used, so that the light guide plate can be fabricated to have a small thickness, for example, 0.5 mm to 2 mm.

In addition, according to exemplary embodiments, even in the case in which the light guide plate is extremely thin, relatively-large LEDs can be used irrespectively, so that high light efficiency can be obtained.

The methods and apparatuses of the present disclosure have other features and advantages that will be apparent from or that are set forth in greater detail in the accompanying drawings, the disclosures of which are incorporated herein, and in the following Detailed Description, which together serve to explain certain principles of the present disclosure.

### BRIEF DESCRIPTION OF DRAWINGS

FIG. 1 is a schematic view illustrating an optical structure for an LED device according to a first exemplary embodiment;

FIG. 2 is a schematic view illustrating a prism shape of a prism sheet in the optical structure for an LED device according to the first exemplary embodiment;

FIG. 3 is a schematic view illustrating an LED device for a lighting application, including the optical structure for an LED device according to the first exemplary embodiment;

FIG. 4 is a schematic view illustrating an optical structure for an LED device according to Comparative Example 1;

FIG. 5 is a schematic view illustrating an optical structure for an LED device according to Example 1;

FIG. 6 is a graph illustrating simulation results of the light efficiency of Example 1 and Comparative Example 1, depending on distance between an LED and a light guide plate;

FIG. 7 is a schematic view illustrating an optical structure for an LED device according to a second exemplary embodiment;

FIG. 8 is a schematic view illustrating a prism shape in the optical structure for an LED device according to the second exemplary embodiment;

FIG. 9 is a schematic view illustrating an optical structure for an LED device according to a third exemplary embodiment;

FIG. 10 is a schematic view illustrating an optical structure for an LED device according to a fourth exemplary embodiment; and

FIG. 11 is a schematic view illustrating an optical structure for an LED device according to a fifth exemplary embodiment.

### BEST MODE FOR CARRYING OUT THE INVENTION

Hereinafter, an optical structure for a light-emitting diode (LED) device, and an LED device for a lighting application including the same, according to exemplary embodiments, will be described in detail with reference to the accompanying drawings.

In the following description, detailed descriptions of known functions and components incorporated into the present disclosure will be omitted in the case in which the subject matter of the present disclosure is rendered unclear by the inclusion thereof.

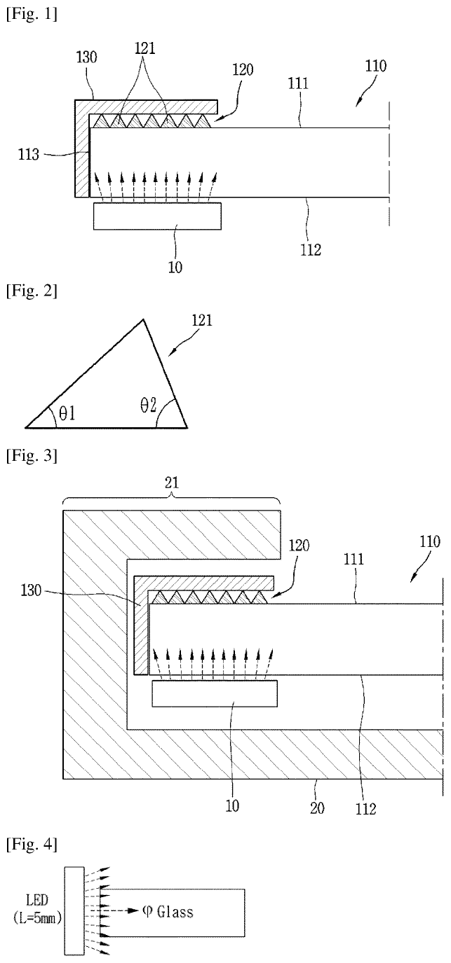

As illustrated in FIG. 1, an optical structure for an LED device according to a first exemplary embodiment is intended to guide light generated by an LED 10 forwardly. The optical structure includes a light guide plate 110 and a prism sheet 120.

The light guide plate 110 is a member generating a planar light source by uniformly distributing light generated by the LED 10 in the direction of the top surface (with respect to the paper surface of the drawing) while minimizing the loss of light. The light guide plate 110 may be provided in the shape of a plate or a pane. Here, in the first exemplary embodiment, a surface, among surfaces of the light guide plate 110, through which light exits, is defined as a first surface 111, for the sake of brevity. In addition, a surface, among the surfaces of the light guide plate 110, facing away from the first surface 111 and toward the LED 10, is defined as a second surface 112.

The light guide plate 110 according to the first exemplary embodiment may be implemented as a glass substrate. Here, the thickness of the light guide plate 110 according to the first exemplary embodiment is not limited by the size of the LED 10. That is, the light guide plate 110 according to the first exemplary embodiment can be fabricated to be very thin, so that the thickness of an LED device to which the light guide plate 110 is applied can be reduced to improve the value of the LED device. For example, the light guide plate 110 may be fabricated to have a thickness of 0.5 mm to 2 mm. The light guide plate 110 can be fabricated to have a reduced thickness or an extremely reduced thickness, irrespective of the size of the LED 10, because the prism sheet 120 is disposed on the first surface 111 of the light guide plate 110 to refract light passing through the light guide plate 110. Hereinafter, the prism sheet 120 will be described in more detail.

The prism sheet 120 is a member refracting light generated by the LED 10, disposed adjacent to the second surface 112 of the light guide plate 110, while allowing the light to pass therethrough, thereby improving light efficiency. The prism sheet 120 according to the first exemplary embodiment is disposed on a peripheral portion of the first surface 111 of the light guide plate 110. Thus, as illustrated in FIG. 3, in an LED device for a lighting application, the prism sheet 120 is converted with a bezel 21 of a frame 20. That is, a front peripheral portion of the optical structure according to the first exemplary embodiment, including the light guide plate 110 and the prism sheet 120, is covered with the bezel 21, i.e. a front portion of the frame 20 providing a mounting space for the light guide plate 110 and the prism sheet 120.

In addition, the prism sheet 120 according to the first exemplary embodiment includes a plurality of prisms 121 continuously arranged in one direction to form a pattern. Here, the plurality of prisms 121 may form a stripe pattern, when viewed on a plane. In addition, in the plurality of prisms 121, pitches between adjacent prisms may range from 15 μm to 40 μm.

In the first exemplary embodiment, prisms of the plurality of prisms 121 may have an asymmetrical structure, with both light-refracting surfaces thereof having different inclinations. For example, prisms of the plurality of prisms 121 may have an asymmetrical cross-sectional shape, with oblique sides thereof being asymmetrical with respect to each other. However, this is only an example, and the prisms 121 may have a variety of asymmetrical shapes. The shape of the prisms 121 according to exemplary embodiments is not necessarily limited to a triangular prism having asymmetrical oblique sides. Here, as illustrated in FIG. 2, the cross-section of the prism 121 may have an asymmetrical cross-sectional shape, with oblique sides thereof being asymmetrical with respect to each other. The prisms 121 having asymmetrical oblique sides can have higher light efficiency than prisms having symmetrical oblique sides. In particular, in the triangle of the cross-section of the prisms 121, one interior angle θ1 between the base and one oblique side may range from 7° to 30° and another interior angle θ2 between the base and the other oblique side may range from 20° to 60° to realize superior light efficiency.

In the optical structure for an LED device according to the first exemplary embodiment, the light guide plate 110 can be fabricated to be very thin, due to the prism sheet 120, irrespective of the size of the LED 10. Since the LED 10 having a relatively-large size can be used even in the case in which the light guide plate 110 is fabricated to be very thin, it is possible to obtain high light efficiency by combining the light guide plate 110 having a very small thickness and the LED 10 having a relatively-large size.

In the first exemplary embodiment, the width of the prism sheet 120 may be set to be the same as or greater than the width of the LED 10 disposed adjacent to the second surface 112 of the light guide plate 110 in order to improve light efficiency. In the first exemplary embodiment, the prism sheet 120 may be attached to the light guide plate 110 via an adhesive. Here, the adhesive may be implemented as a pressure sensitive adhesive (PSA) film, an optically clear adhesive film (OCA), or the like.

In addition, the optical structure for an LED device according to the first exemplary embodiment may further include a reflector 130 disposed on the prism sheet 120. Here, the reflector 130 may extend onto a side surface of the light guide plate 110 in order to reduce light loss in the peripheral portions of the light guide plate 110, i.e. to guide light, exiting the light guide plate 110 through blind spots, into the light guide plate 110. In the first exemplary embodiment, the reflector 130 may be implemented as a diffusing reflector. However, the reflector 130 according to the first exemplary embodiment is not limited to the diffusing reflector, since the reflector 130 may be formed from any material having high reflectance.

Here, sine refracted light exiting the prism sheet 120 is reflected by the reflector 130, disposed on the prism sheet 120, to be redirected toward the LED 10, the LED 10 disposed adjacent to the second surface 112 of the light guide plate 110 may have high reflectance. In addition, the LED 10 may be located as close as possible to the second surface 112 of the light guide plate 110 in order to reduce light loss.

### Comparative Example 1

As illustrated in FIG. 4, simulation was performed by assuming an optical structure in which an LED having a height 5 mm was disposed adjacent to a side surface of a light guide plate having a thickness 0.5 mm. Here, the distance between the light guide plate and the LED was set to be 0 μm.

### Example 1

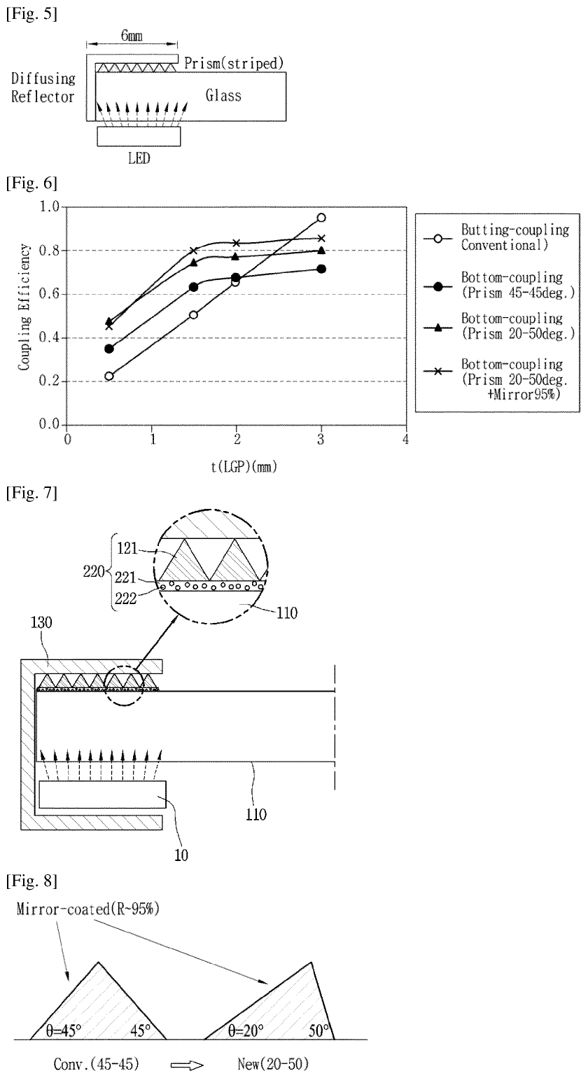

As illustrated in FIG. 5, simulation was performed by assuming an optical structure in which an LED having a width 5 mm and a surface reflectance 90% was disposed adjacent to a peripheral portion of the bottom surface of each of light guide plates having a specific thickness, a prism sheet having a width 6 mm and a typical 45°-45° prism angle was disposed on the top surface of each of the light guide plates, and a reflector having a reflectance 95% and Lambertian light distribution was disposed above the prism sheet and on a side surface of each of the light guide plates. Here, the light guide plates having various thicknesses of 0.5 mm, 1.5 mm, 2.0 mm, and 3.0 mm were used.

FIG. 6 illustrates simulation results of the light efficiency of Example 1 and Comparative Example 1, depending on a distance between the LED and the light guide plate. Referring to FIG. 6, in the case of Comparative Example 1, it was appreciated that, when the thickness of the light guide plate was lower than the height of the LED disposed adjacent to the side surface of the light guide plate, most portions of light exited, instead of being guided. That is, in the case of Comparative Example 1, when the thickness of the light guide plate was 0.5 mm, light efficiency was calculated to be about 21%, as the simulation result. This means that light loss was about 80%.

In contrast, in the case of Example 1 in which the thickness of the light guide plate was the same as that of Comparative Example 1, the prism sheet was disposed on the top surface of the light guide plate, and the reflector was disposed above the prism sheet and on the side surface of the light guide plate, the light efficiencies were calculated to be in the range from 35% to 70%, depending on changes in the thickness of the light guide plate. That is, it was appreciated that, when the light guide plate had a thin thickness 0.5 mm, the light efficiency of Example 1 was improved to be at least 1.6 times the light efficiency of Comparative Example 1.

Hereinafter, an optical structure for an LED according to a second exemplary embodiment will be described with reference to FIG. 7.

FIG. 7 is a schematic view illustrating the optical structure for an LED device according to the second exemplary embodiment.

As illustrated in FIG. 7, the optical structure for an LED device according to the second exemplary embodiment includes the light guide plate 110, a prism sheet 220, and a reflector 130.

The second exemplary embodiment is substantially the same as the first exemplary embodiment, except for the structure of the prism sheet. The same components will be denoted by the same reference numerals and detailed descriptions thereof will be omitted.

The prism sheet 220 according to the second exemplary embodiment may further include a matrix layer 221 and a number of scattering particles 222. Here, the matrix layer 221 is disposed below a pattern of a plurality of prisms 121 of the prism sheet 220. As illustrated in FIG. 8, in the second exemplary embodiment, prisms 121 of the plurality of prisms 121 are implemented as a 20°-50° prism b, in place of a typical 45°-45° prism. The plurality of prisms 121 may be arranged on the matrix layer 221 to form a pattern. In addition, the matrix layer 221 may be disposed on the first surface 111 of the light guide plate 110.

In the second exemplary embodiment, the number of scattering particles 222 are dispersed in the matrix layer 221. The number of scattering particles 222 serve to scatter light passing through the light guide plate 110, and may be formed from a material having a different refractive index from the matrix layer 221.

In addition, the reflector 130 disposed on the prism sheet 220 may extend onto the side surface 113 of the light guide plate 110 and further onto a rear surface of the LED 10, disposed adjacent to the second surface 112 of the light guide plate 110, in order to guide light, having exited the side surface 113 and the second surface 112 of the light guide plate 110, to be redirected into the light guide plate 110.

Since the second exemplary embodiment further includes the matrix layer 221 with the number of scattering particles 222 being dispersed therein, in addition to the prism sheet 220, light efficiency can be further improved.

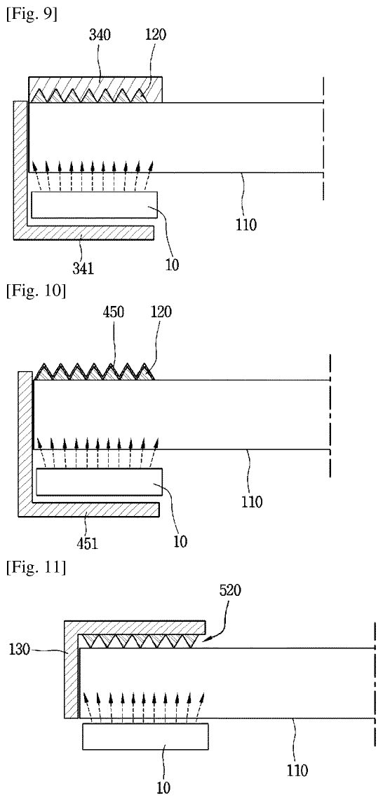

Hereinafter, optical structures for an LED device according to third and fourth exemplary embodiments will be described with reference to FIGS. 9 and 10.

FIG. 9 is a schematic view illustrating the optical structure for an LED device according to the third exemplary embodiment, while FIG. 10 is a schematic view illustrating the optical structure for an LED device according to the fourth exemplary embodiment.

First, as illustrated in FIG. 9, the LED device according to the third exemplary embodiment includes the light guide plate 110, the prism sheet 120, and a reflective layer 340.

In addition, as illustrated in FIG. 10, the LED device according to the third exemplary embodiment includes the light guide plate 110, the prism sheet 120, and a reflective coating layer 450.

The third and fourth exemplary embodiments are substantially the same as the first exemplary embodiment, except for the presence of the reflector (third exemplary embodiment) and the reflective coating layer (fourth exemplary embodiment). The same components will be denoted by the same reference numerals and detailed descriptions thereof will be omitted.

As illustrated in FIG. 9, the reflective layer 340 according to the third exemplary embodiment covers the prism sheet 120. That is, the prism sheet 120 is disposed within the reflective layer 340. Here, the reflective layer 340 has a flat surface. When the reflective layer 340 is provided covering the prism sheet 120, the reflector (130 in FIG. 1), disposed above the prism sheet 120 in the first exemplary embodiment, may be omitted. In addition, in the third exemplary embodiment, an auxiliary reflector 341 may be disposed on the side surface 113 of the light guide plate 110 and adjacent to the rear surface of the LED 10, disposed adjacent to the second surface 112 of the light guide plate 110, in order to guide light, having exited the side surface 113 and the second surface 112 of the light guide plate 110, to be redirected into the light guide plate 110.

In addition, as illustrated in FIG. 10, the reflective coating layer 450 according to the fourth exemplary embodiment may be provided coating a surface of the prism sheet 120. The reflective coating layer 450 may be formed from silver or aluminum. As the surface of the prism sheet 120 is coated with such a material, the reflective coating layer 450 is fabricated along the shape of prisms 121 of the prism sheet 120. When the prism sheet 120 is coated with the reflective coating layer 450 as described above, the reflector (130 in FIG. 1), disposed above the prism sheet 120 in the first exemplary embodiment, may be omitted as in the third exemplary embodiment. In addition, as in the third exemplary embodiment, an auxiliary reflector 451 may be disposed on the side surface 113 of the light guide plate 110 and adjacent to the rear surface of the LED 10, disposed adjacent to the second surface 112 of the light guide plate 110, in order to guide light, having exited the side surface 113 and the second surface 112 of the light guide plate 110, to be redirected into the light guide plate 110.

Hereinafter, an optical structure for an LED device according to a fifth exemplary embodiment will be described with reference to FIG. 11.

FIG. 11 is a schematic view illustrating the optical structure for an LED device according to the fifth exemplary embodiment.

As illustrated in FIG. 11, the optical structure for an LED device according to the fifth exemplary embodiment includes the light guide plate 110, a prism sheet 520, and the reflector 130.

The fifth exemplary embodiment is substantially the same as the first exemplary embodiment, except for the position of the prism sheet. The same components will be denoted by the same reference numerals and detailed descriptions thereof will be omitted.

The prism sheet 520 according to the fifth exemplary embodiment is disposed on a surface of the reflector 130, facing the first surface 111 of the light guide plate 110. Here, the prism sheet 520 may be attached to the surface of the reflector 130 via an adhesive, such as as a pressure sensitive adhesive (PSA) film or an optically clear adhesive film (OCA). The thinner the thickness of the adhesive is, the more advantages the efficiency is.

As described above, the prism sheet 520 may be attached to the surface of the reflector 130 as in the fifth exemplary embodiment, as required or, for example, for the convenience of fabrication. The prism sheet (120 in FIG. 1) may be attached to the first surface 111 of the light guide plate 110, as in the fifth exemplary embodiment.

The foregoing descriptions of specific exemplary embodiments of the present disclosure have been presented with respect to the drawings and are not intended to be exhaustive or to limit the present disclosure to the precise forms disclosed herein, and many modifications and variations would obviously be possible for a person having ordinary skill in the art in light of the above teachings.

It is intended, therefore, that the scope of the present disclosure not be limited to the foregoing embodiments, but be defined by the Claims appended hereto and their equivalents.

### DESCRIPTION OF REFERENCE NUMERALS OF DRAWINGS

110: Light guide plate 111: First surface
112: Second surfaced 113: Side surface
120, 220, 520: Prism sheet 121: Prism
130: Reflector 221: Matrix layer
222: Scattering particle 340: Reflective layer
341, 451: Auxiliary reflector 450: Reflective coating layer
10: LED 20: Frame
21: Bezel

1. An optical structure for a light-emitting diode device, comprising:
a light guide plate comprising a first surface and a second surface facing away from the first surface; and
a prism sheet disposed on a peripheral portion of the first surface, the prism sheet comprising a plurality of prisms continuously arranged in one direction to form a pattern,
wherein the plurality of prisms comprises prisms having an asymmetrical structure in which light-refracting surfaces have different inclinations.

2. The optical structure of claim 1, further comprising a reflector disposed on the prism sheet.

3. The optical structure of claim 1, wherein each of the plurality of prisms comprises a triangular prism.

4. The optical structure of claim 3, wherein each of the plurality of prisms has an asymmetrical cross-sectional shape, with oblique sides thereof being asymmetrical with respect to each other.

5. The optical structure of claim 4, wherein the cross-sectional shape of the prism is configured such that an interior angle formed between a base and one side, of the oblique sides, ranges from 7° to 30° and an interior angle formed between the base and the other side, of the oblique sides, ranges from 20° to 60°.

6. The optical structure of claim 1, wherein the light guide plate and the prism sheet are adhered to each other via an adhesive.

7. The optical structure of claim 1, wherein pitches between adjacent prisms among the plurality of prisms range from 15 μm to 40 μm.

8. The optical structure of claim 1, wherein the plurality of prisms comprise a stripe pattern.

9. The optical structure of claim 1, wherein a width of the prism sheet is equal to or greater than a width of the light-emitting diode.

10. The optical structure of claim 1, wherein the light guide plate comprises a glass substrate.

11. The optical structure of claim 1, wherein a thickness of the light guide plate ranges from 0.5 mm to 2 mm.

12. The optical structure of claim 2, wherein a portion of the reflector extends onto a side surface of the light guide plate.

13. The optical structure of claim 12, wherein the portion of the reflector further extends onto a rear surface of the light-emitting diode.

14. The optical structure of claim 2, wherein the prism sheet is provided on a surface of the reflector, facing the first surface of the light guide plate.

15. The optical structure of claim 1, wherein the prism sheet further comprises:
a matrix layer provided below the plurality of prisms; and
a number of light-scattering particles dispersed in the matrix layer.

16. The optical structure of claim 1, further comprising a reflective layer covering the prism sheet and having a flat surface.

17. The optical structure of claim 1, further comprising a reflective coating layer with which a surface of the prism sheet is coated.

18. A light-emitting device for a lighting application, comprising:
the optical structure according to claim 1;
a light-emitting diode disposed on a rear peripheral portion of the optical structure facing the second surface; and
a frame providing a mounting space in which the optical structure and the light-emitting diode are disposed, and comprising a bezel provided on a front peripheral portion of the optical structure.

19. The optical structure of claim 18, wherein a front peripheral portion of the optical structure is covered with the bezel.
